(19) United States
(12) Patent Application Publication
(10) Pub. No.: US 2018/0040562 A1
(43) Pub. Date: Feb. 8, 2018

(54) ELEKTRONISCHES MODUL UND VERFAHREN ZU SEINER HERSTELLUNG

(71) Applicant: Fraunhofer-Gesellschaft zur Foerderung der angewandten Forschung e.V., Muenchen (DE)

(72) Inventors: Thomas Löher, Berlin (DE); Lars Böttcher, Berlin (DE); Stefan Karaszkiewicz, Berlin (DE); Andreas Ostmann, Berlin (DE)

(21) Appl. No.: 15/669,560

(22) Filed: Aug. 4, 2017

(30) Foreign Application Priority Data
Aug. 5, 2016 (DE) 10 2016 214 607.6

(51) Int. Cl. H01L 23/538; H01L 25/00; H01L 29/739; H01L 25/07

(52) U.S. Cl. CPC H01L 23/5389; H01L 25/072; H01L 25/50; H01L 29/7393; H01L 23/5384

(57) ABSTRACT

The invention relates to an electronic, in particular power-electronic module (28) with a first layer composite (1) which comprises an inner, electrically insulating layer (4), into which one or more semiconductor elements (2, 3) are embedded in a manner such that they are covered at least on their upper side and lower side by the material of the inner layer (4), wherein the first layer composite (1) comprises a metallisation on the lower side and/or upper side, and with a second layer component (9) which on the one hand comprises an electrically insulating layer which faces the first layer composite, as well as comprises a layer which is away from the first layer composite and which has a higher thermal conductivity than that of the electrically insulating layer which faces the first layer composite, or on the other hand comprises a layer whose material electrically insulates and has a higher thermal conductivity than the embedded, unfilled material of the inner layer of the first layer composite, wherein the first layer composite (1) is connected in a surfaced manner to the second layer composite (9) along a joining surface (32). Mechanical problems caused by the different thermal expansions of the first and second substrate (1, 9) are avoided on manufacture of the electronic modules by way of avoiding an integrated manufacture of the first and second substrate and, instead of this, by way of joining together individual substrate sections.

The invention relates to the field of mechanics and electrotechnology or electronics and can be particularly advantageously used in semiconductor technology of power electronics.

According to the known state of the art, electronic, in particular power-electronic elements or modules are often fastened to ceramic substrates by way of soldering or low-temperature sintering. Here, DCB (direct copper bonded) substrates are used as ceramic substrates. Corresponding components such as MOSFETs, IGBTs, diodes or others are usually electrically connected by way of bond wires of aluminum, gold or other materials. Usually, an optimised thermal behaviour of the substrate is realised by way of the provision of relatively thick copper metallisations (300-600 μm Cu thickness), in order to be able to easily lead dissipated heat away from the electronic elements, for example heat produced by switching losses. Moreover, a good electrical insulation can be realised by way of the electrically insulating base material of the substrate (ceramic).

In some cases, the disadvantage of such constructions can be the connection of the components by way of wire bond connections. On the one hand, such bond connections are not completely reliable and prone to damage, particularly with frequent electrical and/or thermal load changes and the bond wires moreover represent relatively large electrical inductances which particularly at high switching frequencies lead to undesirable switching losses and also limit the maximal switching speed.

Against this background of the state of the art, it is the object of this invention to provide an electronic module, concerning which an electrical connection of the components can be ensured in a reliable and low-induction manner. A good cooling behaviour for dissipating heat losses with the electrical functioning of the components is also to be achieved.

This object is achieved by an electronic module with the features of the invention according to patent claim 1.

Patent claims 2 to 18 represent embodiments of the invention.

Patent claims 19 relates to a method for manufacturing an electronic module.

Accordingly, the invention relates to an electronic, in particular power-electronic module with a first layer composite which comprises an inner, electrically insulating layer, into which one or more semiconductor elements are embedded in a manner such that they are covered at least on their upper side and lower side by the material of the inner layer, wherein the first layer composite comprises a metallisation on the lower side and/or upper side, and with a second layer component which on the one hand comprises an electrically insulating layer which faces the first layer composite, as well comprises a layer which is away from the first layer composite and which has a high thermal conductivity, in particular a higher thermal conductivity than that of the electrically insulating layer which faces the first layer composite, or on the other hand comprises a layer, whose material electrically insulates and has a high thermal conductivity, in particular a higher thermal conductivity than the embedded, unfilled material of the inner layer of the first layer composite, wherein the first layer composite is connected to the second layer composite in a surfaced (extensive) manner along a joining surface, and with a joining layer which is arranged between the first layer composite and the second layer composite.

The invention therefore envisages embedding the semiconductor elements of a module into a layer composite. The semiconductor elements are thus well protected and can be contacted within the embedded material by way of different possible measures without the contactings or contacting conductors being exposed to environmental influences, deformation, accelerations or similar influences. The length of conductors which contact the components can also be minimised in this manner, so that the inductances can be reduced. Dissipated power and likewise thermal switching losses are reduced in this manner. The material of the inner layer of the first layer composite which embeds the semiconductor elements is electrically insulating.

In contrast to the conventional chip embedding, a further aspect of the invention envisages the first layer composite being joined and connected to the second layer composite in a surfaced manner. The joining is preferably effected after the separate manufacture of the first and of the second layer composite.

The second layer composite serves as a substrate for the electrical wiring and for heat dissipation of the first layer composite. Here, the first layer composite is not constructed on the second layer composite in a direct manner within the framework of the manufacturing process, but is joined to this within the framework of a joining technique which is known per se, after the manufacture of the first and second layer composite.

Large-surfaced arrays of the first layer composite can be manufactured by way of this, and, preferably after a division into composite sections, can be joined to the second layer composite or to corresponding sections of the second layer composite without thermal effects due to the different thermal characteristics of the first and second layer composite leading to disturbing deformations. Respective differences are partly also compensated by the joining surface itself or also possibly by a joining material which is introduced between the first and the second layer composite.

In the course of the manufacture of the electronic modules according to the invention, a first layer composite with several groups of embedded semiconductors can firstly be manufactured in a large-surfaced manner and thereafter be singularised by way of sawing or cutting. A second layer composite can likewise be manufactured in a larger surface, thereafter singularised by way of sawing or cutting and the individual sections (composite sections) of the second layer composite can be joined to the corresponding sections of the first layer composite into a module according to the invention.

Several separated composite sections of the first layer composite with embedded components can also be each joined to a composite section of the second layer composite which is not yet separated at this point in time, wherein the composite section of the second layer composite is subsequently divided.

Deformations which could arise due to the direct construction of a first layer composite on a second layer composite on larger surface units are avoided in this manner.

Concerning the module, one can envisage at least two semiconductor elements which in particular are of the same type and which are electrically connected in series being embedded into the first layer, and these being arranged such that the through-directions of the useful current in the first and the second semiconductor enclose an angle which is 90 degrees or larger.

By way of this solution, one succeeds in strip conductors between the output of the first semiconductor element and the terminal of a further semiconductor element which is directly connected to this being able to be designed in a very short manner. In contrast, regarding conventional constructions, the leading of the conductor runs vertically via through-contactings from one strip conductor plane to the next and from there to the terminal of the next semiconductor clement. Here, the vertical direction is to be understood as the direction which is perpendicular to the layer plane of the inner layer.

For this, in one embodiment (face up/down variant), one can envisage at least two semiconductor elements which are of the same type and which are electrically connected in series being embedded into the inner layer in alignments which are mirrored to one another at the layer plane of the first layer. The layer plane of the first layer is to be understood here as the plane which lies perpendicular to the direction of the smallest extension of the first layer.

For example, the first semiconductor component can be orientated in the inner layer in a “face up” manner, which means concerning a transistor with the gate/source being orientated at the top or to a first flat side of the inner layer and concerning an IGBT with the emitter being orientated at the top or to a first flat side of the inner layer, whereas the second semiconductor component is orientated “face down”, which means that with regard to a transistor with the gate/source being orientated to the bottom or to the second flat side of the inner layer, and with regard to an IGBT with the emitter being orientated to the bottom or to the second flat side of the inner layer. By way of this, it is possible within the bridge circuit to connect the source/emitter of the one semiconductor element directly to the drain/collector of the second semiconductor element, without hereby having to jump across several layers of the layer composite or of the inner layer. Disturbing inductances and switching losses are reduced by way of this and the switching behaviour is improved.

In a further embodiment (flipped variant) one can envisage at least two semiconductor elements which are electrically connected in series and which in particular are of the same type being embedded into the inner layer in a manner such that a current terminal of one of the semiconductor elements faces the current terminal of a respective other semiconductor element which is to be directly connected to this or that two current terminals of two semiconductor elements which are to be electrically directly connected to one another lie on the same side of the semiconductor elements with respect to the layer plane of the inner layer.

A further realisation possibility of the module envisages the semiconductor elements (2, 3) which are electrically connected in series being transistors or IGBTs for power applications. However, other high-current semiconductor components which can be applied for example in bridge circuits of rectifier technology are also conceivable.

Basically, one can envisage the semiconductor elements which are embedded in the first layer composite consisting at least partly of silicon, silicon carbide or gallium nitride.

Power semiconductors which are used for example for high-frequency switching, such as MOSFETs, IGBTs or diodes, concerning which the switching losses can be well reduced within the framework of the invention, can be manufactured from such semiconductor materials.

Here, one can moreover envisage the semiconductor elements being connected to at least one metallisation of the inner layer or of the first layer composite at least partly by way of vertical contactings vias or microvias).

Vertical contactings are to be understood as those which, starting from the surface of a layer composite, lead into this composite to the terminal of an electronic or electronic component. Such vertical contactings can be realised by way of pin-like conductors or usually by so-called vias or microvias which are formed by blind bores which are filled completely with copper or a conductive paste. However, any other type the leading of the conductors which forms a short as possible conductive connection from the surface of a layer composite into the inside to a semiconductor element can also be envisaged.

One can moreover envisage the inner layer of the first layer composite at least partly consisting of a plastic, in particular of a polymer-based material, in particular an epoxy-based or polyimide-based material.

Such an inner layer is electrically insulating and can be connected for example to a further layer which ensures a good heat dissipation. However, one can also envisage a plastic of the inner layer of the first layer composite being filled with electrically insulating filling bodies, in particular in a granulate form and/or fibre form and/or fabric form and these bodies in particular having a higher thermal conductivity than the plastic of the inner layer, into which they are embedded.

The insulating filling bodies here advantageously have a higher thermal conductivity, i.e. a lower thermal resistance than the plastic, from which the inner layer is formed and in which the filling bodies are embedded. The filling bodies can consist for example of a glass or a ceramic or another comparable material which has a sufficiently high thermal conductance. As a whole, it is advantageous if the inner layer has a thermal conductivity which is larger than 2 W/mK.

For this purpose, the degree of filling, i.e. the volume share of the filling bodies in the volume of the inner layer can advantageously be larger than 20% by volume, in particular larger than 40% by volume.

The second layer composite can comprise a layer with a high thermal conductivity, for example a metal or a ceramic or the second layer composite can also consist completely or mainly of such a material inasmuch as the electrical insulation characteristics can be ensured. The second layer composite can be a ceramic/metal composite such as DCB (direct bonded copper) or AMB (active metal brazing).

Such substances can be used directly as coolers and an envisaged metallisation can be structured in a manner such that the necessary electrical insulation characteristics are achieved in the region of the joining surface between the first and the second layer composite.

One can also envisage the second layer composite comprising a thermally conductive layer with an organic material based on polymer, in particular with inorganic filling particles in granulate form and/or fibre form and/or fabric form.

Here too, one can envisage the filling particles consisting of a material which has a higher thermal conductivity than the material, in which they are embedded. Here too, the filling degrees are greater than 20% by volume, in particular greater than 40% by volume and it is also advantageous for the second layer composite if a thermal conductively of greater than 2 W/mK is achieved.

Here, one can envisage the thermally conductive layer of the second layer composite being structured or unstructured.

One can moreover envisage the second layer composite comprising a thermally conductive layer with anodised aluminium.

The second layer composite can also consist mainly or exclusively of an anodised aluminium layer. This layer ensures a good electrical insulation capability due to the anodising, whereas the aluminium core provides a sufficient thermal conductivity.

Regarding the construction of the electronic module, one can basically envisage the first layer composite being connected to the second layer composite in a surfaced manner along a joining surface by way of bonding, soldering, sintering or laminating.

These joining methods create a sufficiently firm and reliable surfaced connection between the first and the second layer composite, wherein, despite this, a compensation given different thermal expansions of the first and the second layer composite is created in most cases by the joining layer or the joining region. This is particularly but not only the case with joining types, concerning which a joining material is introduced between the first and second layer composite.

The joining-together of the first and second layer composite here can be basically effected in an electrically conductive or non-conductive manner.

Advantageously, the joining of the first and of the second layer composite can also be effected in a manner such that entrapped air (air pockets) is avoided. For example, the joining procedure can take place in a vacuum or the joining methods can be selected in a manner such that the trapping of air and the occurrence of cavities is avoided.

Moreover, in a total construction and whilst using the first and the second layer composite, one can further envisage a third layer composite being arranged on the first layer composite and being connected to this in a surfaced manner, wherein the third layer composite comprises an electrical insulating layer, electronic components, a metallisation and vertical contactings.

By way of this, electronic components which supplement the electronic module and which can be arranged and contacted for example on the surface of the third layer composite in a conventional manner can be provided on the third layer composite. Here, it can be components which do not produce as much waste heat as the elements which are embedded in the first layer composite and which do not conduct large currents and/or concerning which no high switching frequencies are envisaged.

In this manner, the use of chip embedding technology can be focused on or restricted to the semiconductor components (electronic power components), concerning which the greatest advantage is achieved by way of avoiding contacting with bond wires.

One can also envisage a third layer composite being arranged on the first layer composite and being connected to this in a surfaced manner, wherein the third layer composite for heat dissipation comprises a layer, in particular of a ceramic material or of a filled polymer-based. plastic and/or a metallisation.

With this, the third layer composite can also contribute to the heat dissipation of the first layer composite, so that the heat from the first layer composite can be led to one side in the direction of the third layer composite and onwards via this, as well as from the first layer composite at the other side to the second layer composite.

The third layer composite can moreover comprise electrical components and vertical contactings. The third layer composite here can also comprise vertical contactings, by way of which the semiconductor components embedded in the first layer composite are contacted so that corresponding vertical contactings run or are extended, through the third layer composite and into the first layer composite.

For the construction of a complete module, one can also envisage a fourth layer composite being arranged directly on the second layer composite next to a first layer composite and being connected to the second layer composite in a surfaced manner, wherein the fourth layer composite comprises an electrical insulating layer, electronic components, a metallisation and vertical contactings.

The second layer composite which can have a cooling effect and function as a heat sink, next to one another can therefore on the one hand comprise a first layer composite with embedded semiconductor components and a fourth layer composite with non-embedded components which are arranged on the surface of the fourth layer composite. Advantages of embedding technology on the one hand for power semiconductor elements for high switching frequencies can also be optimally combined with a simple construction of other semiconductor components on the surface of the further layer composite by way of such a construction.

Apart from relating to an electronic module of the type explained and described above, the invention also relates to a method for manufacturing a module, concerning which a first layer composite is firstly manufactured, said first layer comprising an inner layer, into which several equal-type units of one or more semiconductor elements are embedded in a manner such that they are covered at least on their upper and lower side by the material of the inner layer, wherein the first layer composite comprises a metallisation on the lower side and/or upper side, and whereby the first layer composite is subsequently divided into individual sections and the sections of the first layer composite are subsequently joined and connected to a second layer composite in a surfaced manner, said second layer composite on the one hand comprising an electrically insulating layer as well as a layer with a high thermal conductivity, or on the other hand comprising a layer whose material is electrically insulating as well as has a high thermal conductivity, wherein on joining to the sections of the first layer composite, the second layer composite can already be divided into sections (composite sections) which are assigned to the sections of the first layer composite, or the second layer composite can be present in an undivided mariner, wherein in this case the second layer composite is divided after the joining to the sections of the first layer composite.

Deformations due to a thermal treatment as a result of different thermal coefficients of expansion of the first and second layer composite which could arise on or after joining together large surfaced elements are avoided on account of the first layer composite being divided into sections when these are joined to the second layer composite. This applies to the methods of joining individual sections of the first layer composite onto a larger surface of the second layer composite and subsequently cutting the second layer composite along the borders of the first sections, just as to the methods of dividing the first as well as the second layer composite into corresponding sections and individually joining together the sections of the first and second layer composite which match one another into electronic modules by way of the joining methods mentioned above.

For manufacturing the inner layer with the embedded semiconductor elements/electronic power components, these can either be fixed on a common base, for example on a copper foil, the inner layer laminated thereon and the vertical contacts incorporated by microvias from both sides of the inner layer.

However, one can also envisage at least two semiconductor elements being deposited onto separate carrier substrates, for example in the form of copper foils, one of these carrier substrates being joined to the second carrier substrate in a reverse manner such that the semiconductor elements are arranged between the two carrier substrates, and the two carrier substrates being laminated thereon into an inner layer. A vertical contacting of each of the semiconductor elements can then be effected from only a single side of the inner layer by way of microvias.

The invention is hereinafter shown and subsequently described by way of embodiment examples in figures of a drawing. Here, there are shown in

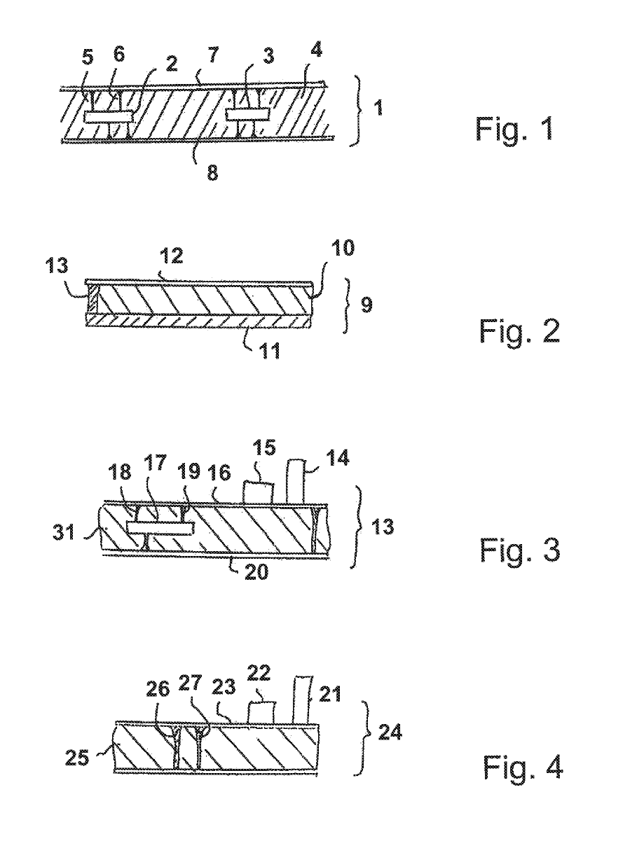

FIG. 1 an embodiment of the first layer composite,

FIG. 2 an embodiment of the second layer composite,

FIG. 3 an embodiment of a third layer composite,

FIG. 4 an embodiment of a fourth layer composite,

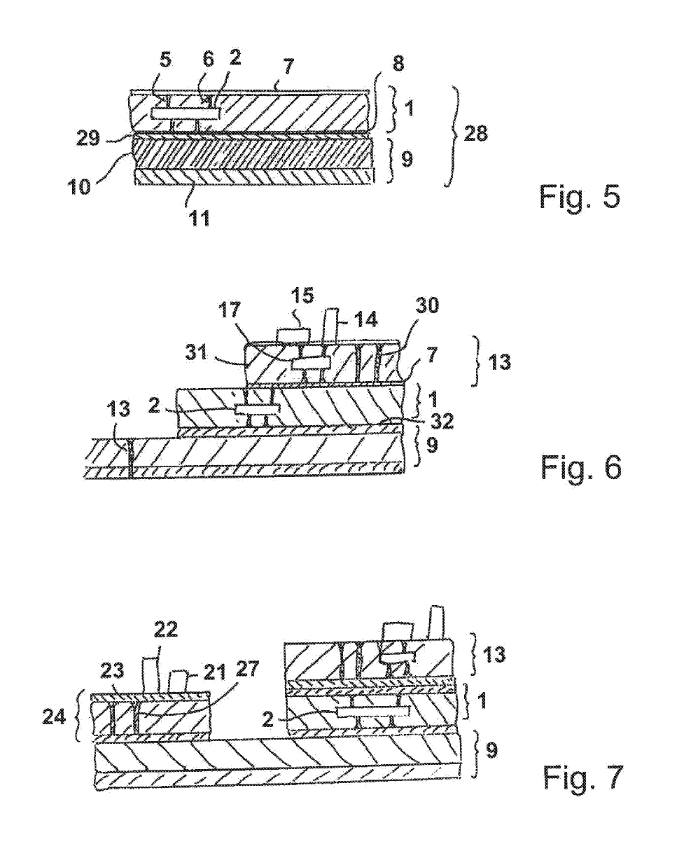

FIG. 5 an electronic module with a first and a second layer composite,

FIG. 6 a module with a first, a second and a third layer composite,

FIG. 7 a module which comprises a first, second, third and fourth layer composite,

FIG. 8 an inner layer with semiconductor elements which are electrically connected to one another and

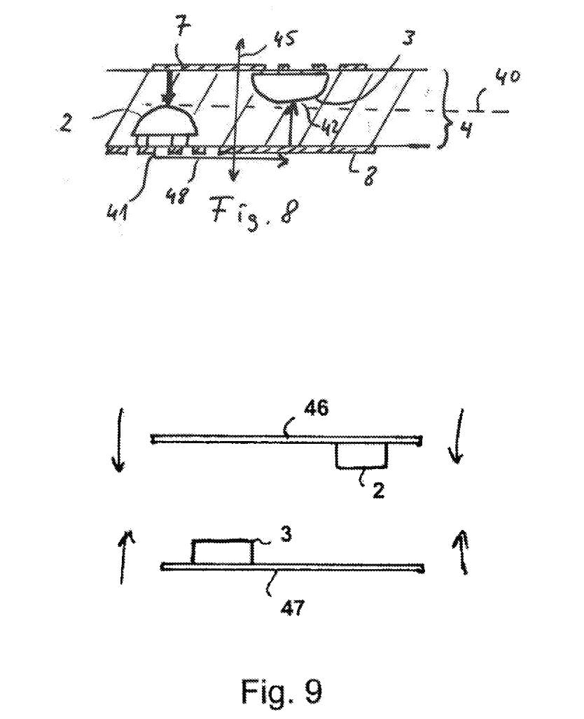

FIG. 9 a method step, concerning which two carrier substrates each with at least one semiconductor element are joined together into an inner layer.

FIG. 1 shows a first layer composite 1 with embedded power semiconductors 2, 3 which are embedded into an insulating inner layer 4. The embedding of the semiconductor elements 2, 3 can be effected for example by way of laminating different organic layers, for example based on polymer, or by way of moulding into an organic material. The inner layer 4 covers the semiconductor components 2, 3 on their upper sides as well as lower sides. The semiconductor elements 2, 3 are conductively connected to a metallic cover layer 7 and/or to a metallic lower layer 8 by way of vertical contacting 5, 6 (vias, microvias). Concerning the first layer composite 1, a metallisation 7, 8 which can also be structured can be provided either on the lower side and upper side or only one the two sides.

The first layer composite 1 in the form of a composite section represents one of the elements of a power-electronic module according to the invention.

A second layer composite 9 which is joined to the first layer composite 1 into a power-electronic module within the framework of the manufacturing method is represented in FIG. 2.

The second layer composite 9 comprises for example an electrically insulating layer 10 of a ceramic or a polymerised plastic as well as a thermally well conducting metallic layer 11 on the lower side. The material of the first layer 10 of the second layer composite can advantageously also itself be well thermally conductive and for this reason, if it consists of a polymer-based material, can be filled with thermally well conductive filling particles such as granulate, fibres and/or fabrics, DCB (direct bonded copper). AMB (active metal brazing) for example are considered as bonds for the second layer composite and basically LTCC (low temperature co-fired ceramic) and HTCC (high temperature co-fired ceramic) are considered as materials. The second layer composite 9 can be provided on its upper side with a structured metal layer 12 which however should be designed such that the electrical insulation characteristics can be ensured in the regions, in which an electrical insulation of the first layer composite is necessary on its lower side.

The second layer composite 9 can moreover also realise electrical connections 40 which lead through from its upper side to the lower side and connect an electrically conductive cover layer to an electrically conductive lower layer.

FIG. 3 shows a third layer composite 13 which carries electronic components 14, 15 on its upper side. These can be arranged on a structured metallisation 16 which serves for the contacting.

Semiconductor components 17 which can be contacted by vias or microvias 18, 19 can also be potentially embedded in the inside of the third layer composite 13. A metallisation, in particular a structured metallisation 20 can be provided on the lower side of the third layer composite 13. As to how elements of a third layer composite 13 can be combined with a module which comprises a first layer composite 1 and a second layer composite 9 is explained further below.

The third layer composite 13 can realise an electrical wiring/contacting carry active and passive components and additionally dissipate waste heat well.

A fourth layer composite which is represented by way of example in FIG. 4 can also be connected to the electronic module which comprises a first layer composite 1 and a second layer composite 9. Such a fourth layer composite can comprise electrical components without it usually having a good thermal conductivity, so that the fourth layer composite does not serve for heat dissipation in contrast to the third layer composite. Electronic components 21, 22 which are arranged on a metallisation 23 of the fourth layer composite 24 are represented by way of example on the fourth layer composite. The fourth layer composite 24 can consist for example of a polymer layer 25 with metallisations on one or both flat sides or comprise at least one polymer layer. Through-contactings 26, 27, for example in the form of metal pins or vias which pass through the complete fourth layer composite 24 can be provided.

An electronic module 28, in which a first layer composite 1 is joined to a second layer composite 9 amid the intermediate addition of a joining layer 29, is shown in FIG. 5. The joining layer 29 can be realised as a bonding material or soldering material, be electrical conductive or insulating and for example be without air pockets.

A power semiconductor element 2 is shown within the first layer composite 1, said power semiconductor element being connected by way of vias 5, 6 on the one hand to the metallisation 7 of the first layer composite and on the other hand to the metallisation 8 on the lower side of the first layer composite. The second layer composite 9 comprises an inner ceramic layer 10 and on its lower side a metallisation layer 11. The ceramic layer 10 is sufficiently thermally conductive, in order to vertically dissipate heat losses of the component 2; in particular, the thermal conductivity of the layer 10 of the second layer composite is larger than that of the first layer of the first layer composite 1. The metallisation layer 11 acts as a heat sink and absorbs dissipated heat from the ceramic layer 10 and possibly leads this further.

The joining layer 29 can be designed for example in a ductile manner, in particular be more ductile than at least one of the layers of the first and second layer composite which are adjacent to the joining layer, so that it compensates differences in the thermal expansion of the first layer composite 1 and of the second layer composite 9. If the joining layer 29 is not as ductile as the materials of the first and second layer composite, then despite this it can act in a compensating manner for the different thermal expansions of the first and second layer composite.

In the case that the first and second layer composite are joined together in a direct manner without the intermediate joining of a joining layer 29, for example by way of sintering or welding, the characteristic of the module of, to a certain extent, compensating mechanical stress as a result of different thermal expansions, results in the region of the joining location.

For example, a polymer-based plastic layer which is filled with inorganic filling bodies which have a higher thermal conductivity than the base material can also be used as the inner layer 10 of the second layer composite 9 instead of the ceramic layer. Such a layer can likewise comprise a metallisation 11 on its lower side or such a layer 11 can also be done away with given an adequate thermal conductivity.

A combination of a module 28 with a first layer composite 1 and a second layer composite 9 and of a third layer composite 13 is represented in FIG. 6.

Within the module 28, the second layer composite 9 projects laterally beyond the first layer composite 1 and provides a through-contacting 30 in the region which projects beyond the first layer composite. The first layer composite 1 on its upper side carriers a third layer composite 13 which carries components 14, 15 which are arranged on a metallisation on the surface of the third layer composite 13 and well as an embedded component 17 which is contacted vertically by way of vias. The third layer composite moreover comprises through-contactings 30 which can serve for contacting the metallisation 7 on the surface of the first layer composite 1.

The third layer composite can comprise for example a layer 31 of an electrically insulating and thermally well conductive material, for example of a polymer which is filled with thermally well conductive filling bodies in granulate form, fibre form and/or fabric form. In this manner, the third layer composite 13 can serve for the heat dissipation of the first layer composite 1 in the region, in which the two layer composites are joined together. The same joining methods as on joining together the first and second layer composite can be applied on joining together the first and the third layer composite. Here too, the joining can be effected amid the intermediate joining of a joining layer or without the intermediate introduction of a joining layer.

For example, one can envisage the first layer composite 1 carrying a metallisation 7 on its upper side and the third layer composite 13 likewise comprising a metallisations on a lower side, so that the two metallised layers can be joined together.

Apart being placed onto the upper side of the first layer composite 1, a third layer composite 13 can also be placed directly onto a second layer composite 9 next to a first layer composite 1.

FIG. 7 shows the supplementing of an electric module 28 which comprises a first layer composite 1 and a second layer composite 9, by a third layer composite 13 and a fourth layer composite 24. The characteristic of the joining-together of the first, second and third layer composite on the right side of the representation of FIG. 7 is not explained further here and the description concerning FIG. 6 is referred to.

The second layer composite 9 projects laterally significantly beyond the first layer composite 1 and carries a fourth layer composite 24 on the projecting part. This fourth layer composite on its upper side which is provided with a metallisation 23 comprises electrical components 21, 22 and provides through-contacting in the form of vias 27. The fourth layer composite 24 consists of a material which is manufactured for example on the basis of polymer and which has no particularly good thermal conductivity, for example is not filled with thermally conductive filling bodies. Inasmuch as this is concerned, it differs from a third layer composite 13 which has a higher thermal conductivity than the fourth layer composite. Heat can be extracted from the fourth layer composite 24 by the second layer composite 9.

Different types of circuits with the desired thermal and heat dissipation characteristics can be constructed by way of the combination of the four described layer composites on the basis of the advantages of the joining-together of the first and second layer composite.

FIG. 8 as an exemplary construction of the inner layer 4 of the first layer composite shows two semiconductor elements, for example transistors or IGBTs 2, 3 which are joined together in a mirror-inverted manner, which is to say that the semiconductor element 3 with respect to its orientation/alignment is mirrored with respect to the semiconductor element 2 at the layer plane 40 of the inner layer 4. This is represented symbolically by way of the sides of the semiconductor elements which are equal with regard to the function each being represented in the same manner—either in a straight manner or arcuately. The layer plane 40 of the first layer 4 is perpendicular to the plane of the drawing.

The terminals 41 and 42 of the semiconductor elements 2 and 3 are connected to one another over a very short path and essentially without an extension of the conductor in the vertical direction 45. The semiconductor element 2 is conductively connected to the metallic cover layer 7, just as the semiconductor element 3. The cover layer 7 is structured.

FIG. 9 shows a step in the course of manufacture of an inner layer 4, wherein concerning the represented variant two semiconductor elements 2, 3 are fixed and contacted on separate metallic carrier substrates 46, 47 by way of sintering. After a 180 degree reversal of the one carrier substrate, the carrier substrates 46, 47 are joined together in a manner such that the semiconductor elements lie between the carrier substrates. The carrier substrates are laminated thereon and the inner layer 4 is thus formed. The semiconductor element 3 is subsequently yet contacted from the side of the carrier substrate 2 by way of microvias, whereas the semi-conductor element 2 is contacted from the side of the carrier substrate 47.

Further special aspects of the invention which can also be realised per se and can represent the invention:

### First Aspect:

Electronic module, with a first layer composite which comprises an inner layer, wherein the first layer composite comprises a metallisation on the lower side and/or the upper side, and wherein at least two semiconductor elements which in particular are of the same type and which are electrically connected in series are embedded into the inner layer, and these are arranged in a manner such that the through-directions of the useful current in the first and in the second semiconductor element enclose an angle which is 90 degrees or larger, or that the conductor leading between the semiconductor elements is shortened to a minimal length.

### Second Aspect:

Electronic module with a first layer composite which comprises an inner layer, wherein the first layer composite comprises a metallisation on the lower side and/or the upper side, and wherein at least two semiconductor elements which are of the same type and which are electrically connected in series are embedded into the inner layer in alignments which are mirrored to one another at the layer plane of the first layer.

### Third Aspect:

An electronic module with a first layer composite which comprises an inner layer (4), wherein the first layer comprise comprises a metallisation on the lower side and/or the upper side, and wherein at least two semiconductor elements which in particular are of the same time and which are electrically connected in series are embedded into the inner layer in a manner such that a current terminal of one of the semiconductor elements faces the current terminal of a respective other semiconductor element which is to be directly connected to this or two current terminals of two semiconductor elements which are to be electrically connected to one another in a direct manner lie on the same side of the semiconductor elements with regard to the layer plane of the inner layer.

### Fourth Aspect:

An electronic module according to one of the preceding aspects, concerning which the semiconductor elements which are electrically connected in series are transistors or IGBTs.

These aspects can further be potentially combined with individual or several features of the patent claims of this patent application.

1. An electronic module (28)
with a first layer composite (1) which comprises an inner, electrically insulating layer (4), into which one or more semiconductor elements (2, 3) are embedded in a manner such that they are covered at least on their upper side and lower side by the material of the inner layer (4), wherein the first layer composite (1) comprises a metallisation on the lower side and/or upper side,
and with a second layer component (9) which on the one hand comprises an electrically insulating layer which faces the first layer composite, as well as comprises a layer which is away from the first layer composite and which has a higher thermal conductivity than that of the electrically insulating layer which faces the first layer composite, or on the other hand comprises a layer whose material electrically insulates and has a higher thermal conductivity than the embedded, unfilled material of the inner layer of the first layer composite, wherein the first layer composite (1) is connected in a surfaced manner to the second layer composite (9) along a joining surface (32),
and with a joining layer (29) which is arranged between the first layer composite and the second layer composite.

2. An electronic module according to claim 1, characterised in that at least two semiconductor elements (2, 3) which are electrically connected in series are embedded into the inner layer (4), and that these are arranged in a manner such that the through-directions of the useful current in the first and the second semiconductor enclose an angle which is 90 degrees or larger.

3. An electronic module according to claim 1 or 2, characterised in that at least two semiconductor elements (2, 3) which are of the same type and which are electrically connected in series are embedded into the inner layer (4) in alignments which are mirrored to one another at the layer plane (40) of the first layer (4).

4. An electronic module according to one of the preceding claims, characterised in that at least two semiconductor elements (2, 3) which are electrically connected in series are embedded into the inner layer (4) in a manner such that a current terminal (41, 42, 43, 44) of one of the semiconductor elements faces the current terminal (41, 42, 43, 44) of a respective other semiconductor element which is to be directly connected to this or that two current terminals (41, 42, 43, 44) of two semiconductor elements (2, 3) which are to be electrically directly connected to one another lie on the same side of the semiconductor elements with respect to the layer plane (40) of the first layer (4).

5. An electronic module according to one of the preceding claims, characterised in that the semiconductor elements (2, 3) which are electrically connected in series are transistors or IGBTs.

6. An electronic module according to one of the preceding claims, characterised in that the semiconductor elements (2, 3) consist at least partly of silicon, silicon carbide or gallium nitride.

7. An electronic module according to one of the preceding claims, characterised in that the semiconductor elements (2, 3) are connected to at least one metallisation (7) of the inner layer (4) or of the first layer composite (1) at least partly by way of vertical contactings (5, 6).

8. An electronic module according to one of the preceding claims, characterised in that the first layer composite (1) is metallised on its lower side as well as upper side and that semiconductor elements (2, 3) are connected to at least one metallisation (7) of the first layer composite (1) at least partly by way of vertical contactings (5, 6).

9. An electronic module according to one of the preceding claims, characterised in that the inner layer (4) of the first layer composite (1) consists at least partly of a plastic.

10. An electronic module according to claim 9, characterised in that a plastic of the inner layer (4) of the first layer composite (1) is filled with electrically insulating filling bodies, in particular in granulate form and/or fibre form and/or fabric form.

11. An electronic module according to one of the preceding claims, characterised in that the second layer composite (9) comprises a ceramic/metal composite.

12. An electronic module according to one of the preceding claims, characterised in that the second layer composite (9) comprises a thermally conductive layer (10, 11) with an organic material based on polymer.

13. An electronic module according to claim 11 or 12, characterised in that the thermally conductive layer (10, 11) of the second layer composite (9) is structured

14. An electronic module according to one of the preceding claims, characterised in that the second layer composite (9) comprises a thermally conductive layer (10, 11) with anodised aluminium.

15. An electronic module according to one of the preceding claims, characterised in that the first layer composite (1) is connected to the second layer composite (9) in a surfaced manner along a joining surface (32) by way of a bonded connection, a soldered connection, a sintered connection or laminated connection.

16. An electronic module according to one of the preceding claims, characterised in that a third layer composite (13) is arranged on the first layer composite (1) and is connected to this in a surfaced manner, wherein the third layer composite (13) comprises an electrical insulating layer (31), electronic components (14, 15), a metallisation (16, 20) and vertical contactings.

17. An electronic module according to one of the preceding claims, characterised in that a third layer composite (13) is arranged on the first layer composite (1) and is connected to this in a surfaced manner, wherein the third layer composite (13) for heat dissipation comprises a layer (31), in particular of a ceramic material or of a filled, polymer-based plastic, and/or a metallisation.

18. An electronic module according to one of the preceding claims, characterised in that a fourth layer composite (24) is arranged directly on the second layer composite (9) next to a first layer composite (1) and is connected to the second layer composite (9) in a surfaced manner, wherein the fourth layer composite (24) comprises an electrical insulating layer, electronic components (21, 22), a metallisation (23) and vertical contactings (26, 27).

19. A method for manufacturing an electronic module according to one of the patent claims 1 to 18, with which a first layer composite (1) is firstly manufactured, said first layer composite comprising an inner layer (4), into which several equal-type units of one or more semiconductor elements (2, 3) are embedded in a manner such that they are covered at least on their upper and lower side by the material of the inner layer (4), wherein the first layer composite (1) comprises a metallisation on the lower side and/or upper side, and that the first layer composite (1) is subsequently divided into individual composite sections and the composite sections (1) of the first layer composite (1) are subsequently joined and connected to a second layer composite (9) in a surfaced manner, said second layer composite on the one hand comprising an electrically insulating layer as well as a layer with a high thermal conductivity, or on the other hand comprising a layer whose material is electrically insulating as well as has a high thermal conductivity, wherein on joining together with the composite sections of the first layer composite (1), the second layer composite (9) is already divided into composite sections which are assigned to the composite sections of the first layer composite (1), or the second layer composite is present in an undivided manner, wherein in this case the second layer composite (9) is divided after the joining-together with the composite sections of the first layer composite (1).
